(19) United States
(12) Patent Application Publication
(10) Pub. No.: US 2015/0212139 A1
(43) Pub. Date: Jul. 30, 2015

(54) SENSITIVE AND SELECTIVE GROUND FAULT DETECTION

(71) Applicant: GF Technologies, LLC, Bluefield, VA (US)

(72) Inventor: Henry D. Smith, Bluefield, WV (US)

(21) Appl. No.: 14/601,669

(22) Filed: Jan. 21, 2015

Related U.S. Application Data
(60) Provisional application No. 61/931,082, filed on Jan. 24, 2014.

(51) Int. Cl. G01R 31/02; G01R 21/00

(52) U.S. Cl. CPC G01R 31/025; G01R 21/00

(57) ABSTRACT

Methods, systems, and devices for sensitive and selective identification of ground faults in a three phase power distribution system are described. The three phase conductors of the three phase power distribution system may be surrounded by a sensor comprising a magnetic ring with a thin opening, and a sensitive magnetometer that operates on magnetoresistance may be disposed in the opening of the ring. The output voltage of the magnetometer is proportional to the magnetic field in the opening of the magnetic ring and is proportional to ground current that transits the magnetic ring and returns outside the ring on the ground system. Comparison of the quantity and/or phase angle between the sensed circuit current and the current in the neutral can determine whether the current is inherent capacitive current or a ground fault.

### CROSS-REFERENCE TO RELATED APPLICATIONS

The present application relies on and claims priority to and the benefit of the filing date of U.S. Provisional Application No. 61/931,082 filed Jan. 24, 2014, the disclosure of which is hereby incorporated by reference in its entirety.

### BACKGROUND OF THE INVENTION

1. Field of the Invention

The present invention relates to ground fault detection in three phase electrical power distribution systems comprising three phase conductors and a neutral. More particularly, the present invention relates to methods, devices, and systems for both sensitive and select identification of true ground faults through the combination of use of a sensitive magnetoresistive sensor and comparison of the quantity and phase angle between the sensed circuit current and current in the neutral.

2. Description of Related Art

Industrial and commercial three phase electrical power distribution systems are typically Wye connected with the neutral point connected to ground. A typical three phase electric power distribution system is shown in FIG. 1 comprising three power lines 12, 14, and 16 Wye connected at a transformer 17 and including a neutral 19 connected to ground 25. An unintentional connection, a fault, from a power phase conductor to ground will cause current to flow from the subject power phase conductor to the circuit grounded neutral.

Limiting the amount of ground current that can flow by placing a resistor between the source neutral and ground has been used by certain industries for decades. A three phase electric power distribution system with a resistor 21 placed between neutral 19 and ground 25 is shown in FIG. 2. Also shown is a phase-to-ground capacitance 22, 24, and 26 for each of the respective power lines 12, 14, and 16. Reducing the current flow during a ground fault reduces the risk from flash burns and fire and also the voltage rise on items such as equipment frames. Some industrial settings, such as coal mining, have specific codes and laws that regulate ground current. For example, the Mine Safety and Health Administration (MSHA) has established maximum ground fault current limits of 1.0 A and 0.5 A for 2400-V and 4160-V systems, respectively (See Novak, The Effects of Very-High-Resistance Grounding on the Selectivity of Ground-Fault Relaying in High-Voltage Longwall Power Systems, IEEE Transactions on Industry Applications, 37(2), 398-420, 2001). In a resistance grounded system, the maximum ground-fault current is controlled by the ohmic value of the resistor, as long as the resistor current is significantly greater than the system capacitive charging current. The lower fault current in such a system can virtually eliminate arcing and flashover dangers, while limiting the amplitude of overvoltages. High resistance grounding is required in underground mining operations relying on resistance-grounding systems. However, a problem with resistance grounding systems is that capacitive currents may cause erroneous tripping of circuits other than the faulted circuit, thus reducing selectivity of the system.

As the levels of ground currents have been lowered by regulatory requirements, there is a greater need for more sensitive ground fault current detection. Thus, there has been a continuing push in the electrical industry for very sensitive ground fault detection systems. Conventional fault detection methods for power transmission systems have included the use of impedance-based methods and traveling wave-based locators. Conventional impedance-based fault location methods use the voltages and currents at one or both ends of a transmission line to determine where a fault has occurred. Traveling wave based methods are based on the fact that faulted circuits produce transients that propagate along the transmission lines as waves. The faults are located by precisely time-tagging wave fronts as they cross a known point such as a substation. However, these have not adequately addressed the need for more sensitive ground fault detection.

As ground fault detection systems move to detection of very low levels of current there is a problem caused by the inherent phase-to-ground capacitances 22, 24 26 of each phase conductor 12, 14, 16 to ground. This is shown in the faulted circuit diagram of FIG. 3 wherein a fault 50 occurs in power line 12 and the faulted current 18 returns to ground 25. Element 27 represents the resistance of the return ground circuit 18. A typical power system will have several circuits 12, 14, 16 served from the same source each with a circuit breaker 42, 44, and 46 and ground fault current detector (not shown). During a ground fault on any circuit, current also flows in the capacitive system of the unfaulted circuits. The capacitive current of each circuit is detected by its ground fault detector, and will trip the circuit breaker for that circuit if it is above the trip level. The result is that not only will the faulted circuit be tripped, but other circuits on the system will be tripped as well even though there is no problem on them. Besides the inconvenience of a false trip, it can result in hazardous situations.

Two factors must be provided for a successful ground fault current detection system. First, a sensitive device to detect and measure ground fault current is needed. Second, a method is needed to determine whether the current detected is flowing into a faulted circuit or is capacitive current flowing into an unfaulted circuit. The result of such a system is that the ground fault current will be quickly detected and only the faulted circuit will be tripped.

Other ground current detecting systems for use on individual circuits rely on the principal that the sum of the currents in a circuit is equal to zero. By summing the currents of the power conductors, any deviation from zero is the measurement of the ground current returning over the ground system.

Conventional sensitive current detectors sum the currents in the power conductors by passing the power conductors through the window of a window type current transformer (CT). In a typical longwall mining system, the three phase conductors pass through the core of the CT and make up its primary, while the grounding conductor remains outside the CT window. Thus, the resulting secondary current is proportional to the phasor sum of the three phase currents. With no ground fault, the magnetic fields of the three phase currents sum to zero, and no current flows through the secondary of the CT. However, if a ground fault occurs, current may return external to the CT core. Thus, as shown in FIG. 4A, any current going out through a window type current transformer 100 on a power conductor that returns over the ground system outside the window results in ampere turns of excitation on the core that is proportional to the current flowing through the fault that is returning over the ground system. This is transformed into voltage on the transformer secondary. Thus, in the presence of a ground fault, current has a return path external to the CT core, creating an imbalance in the line current, which creates a magnetic field that induces a current in the CT secondary that is proportional to the ground fault current. However, it is possible for the ground fault current that originates in a circuit to pass through other circuits as it returns to the source, which can result in a lack of selectivity of the system due to false detection of ground faults in the other circuits.

A number of attempts have been made to address ground fault detection and related issues, including those described in U.S. Pat. Nos. 3,852,642; 4,138,707; 4,203,142; 4,338,475; 4,321,643; 5,181,026; 5,343,155; 7,068,040; 7,301,739; 7,323,880; 7,808,245; 7,834,636; 7,834,636; 7,978,446; 8,300,369; U.S. Patent Application Nos. 2007081281 and 2011075304; Japanese Patent JP2010025743 (“Fumio et al.”), and International Patent Application Nos. WO2012097825 (“Luo”) and WO2006035519, as well as non-patent literature, including “Fault Location for Power Transmission Systems Using Magnetic Field Sensing Coils,” Thesis of K. J. Ferreira, Worcester Polytechnic Institute, April 2007; “Analysis of Magnetic Field Distribution in a Hall Sensor Based Protection,” Miedzinski, et al., Electronics and Electrical Engineering, no. 4(84) (2008); “A New Technique for Location of Fault Location on Transmission Lines,” Alzyoud, et al., Modern Applied Science, vol. 4 no. 8 (2010). These efforts have included the use of magnetic field sensors such as Hall effect sensors in place of window CT sensors as disclosed in the patent applications by Luo and Fumio et al., as well as other publications (See Ferreira, Fault Location for Power Transmission Systems Using Magnetic Field Sensing Coils, Worcester Polytechnic Institute, April 2007; Miedzinski et al., Analysis of Magnetic Field Distribution in a Hall Sensor Based Protection, Electronics and Electrical Engineering, 84(4), 2008; Alzyoud et al., A New Technique for Location of Fault Location on Transmission Lines, Modern Applied Science, 4(8), 2010). However, despite these efforts, there still remains a need in the art for ground fault detection systems with improved sensitivity and selectivity.

### SUMMARY OF THE INVENTION

To this end, the present invention provides methods, systems, and devices for detecting ground fault current in three phase electrical distribution systems. In embodiments, the invention includes a device that is able to detect small amounts of ground current by using an extremely sensitive magnetic field sensor instead of a window current transformer. In embodiments, the sensitive magnetic sensor comprises a magnetoresistive material. The sensitive magnetic field sensor can be used to measure the magnetic field of the summed magnetic flux produced from the load current in the power leads. Additional embodiments include a sensitive magnetic field sensor that can measure the flux produced from a very small amount of ground current. The detected ground current can be analyzed to determine if it is capacitive or resistive. If the current is capacitive, the circuit is not tripped, which results in prevention of false tripping. In embodiments, the circuit is tripped only if the current is resistive.

The present invention, in embodiments, uses a unique method of current detection. The system of the invention will work with conventional devices such as current transformers, but can be made more sensitive by using the device of the invention. In embodiments, the device can be used in systems with or without ground neutral resistors.

Particular aspects of the invention include Aspect 1, which is a method of detecting a fault in an electrical power distribution system, the method comprising: summing currents in power conductors of a circuit to determine a fault condition; determining one or both of magnitude and phase angle of the current in each power conductor and of a current in neutral; and comparing the magnitude and/or phase angle of one or more of the power conductors to that of the current in neutral; and determining by way of the comparing which power conductor has a fault and/or which power conductor has capacitive charging current; wherein optionally the summing is performed using a detector comprising a magnetic core and a sensor comprising a magnetoresistive material, which sensor is disposed within an opening of the magnetic core; and/or wherein optionally the magnetic core surrounds the power conductors; and/or wherein optionally the sensor is operably configured to measure magnetic field intensity, which is proportional to ground current that enters the core and returns outside the core, and the sensor is operably configured to output a voltage that is proportional to the magnetic field intensity; and/or optionally wherein the electrical power distribution system is a three-phase electrical power distribution system.

Aspect 2 is the method of Aspect 1, wherein the sensor measures magnetic flux that results from current being diverted to ground as a result of a fault.

Aspect 3 is the method of Aspect 1 or 2, wherein the magnetoresistive material is a ferromagnetic thin film permalloy.

Aspect 4 is the method of any of Aspects 1-3, wherein the magnetic core is a toroid-shaped magnetic ring comprising a laminated steel core.

Aspect 5 is a method of detecting ground current comprising: measuring magnetic flux generated by power conductors of a three phase electrical power distribution system using a detector surrounding the power conductors and comprising a magnetic core in operable communication with a sensor, wherein the sensor is disposed in a gap within the magnetic core; wherein the magnetic flux is indicative of an amount of current diverted to ground and wherein optionally the sensor converts the magnetic flux to a voltage output; and/or wherein optionally milliampere currents are measured.

Aspect 6 is the method of Aspect 5, wherein the sensor converts the magnetic flux to a voltage output by way of a magnetoresistive material.

Aspect 7 is the method of Aspect 6, wherein the magnetoresistive material is a ferromagnetic thin film permalloy.

Aspect 8 is a method of distinguishing a faulted circuit from a circuit with a capacitive charging current in a three-phase electrical power distribution system comprising three phase conductors and a neutral, the method comprising: measuring current through one or more phase conductors; measuring current through the neutral; and comparing the magnitude and phase angle between the current through one or more of the phase conductors and current through the neutral to distinguish a faulted circuit from a circuit with a capacitive charging current.

Aspect 9 is the method of Aspect 8, wherein current is measured through the phase conductors and the neutral using a magnetometer.

Aspect 10 is the method of Aspect 9, wherein the magnetometer converts a magnetic field to an output voltage through magnetoresistance.

Aspect 11 is the method of Aspect 8 or 9, wherein the magnetometer comprises a ferromagnetic thin film permalloy.

Aspect 12 is the method of any of Aspects 8-11, wherein the phase conductors are surrounded by a toroid-shaped magnetic core, the core comprises an opening, and the magnetometer is disposed in the opening.

Aspect 13 is the method of any of Aspects 8-12, wherein the magnetic core comprises steel, and optionally laminated steel.

Aspect 14 is a method of distinguishing a faulted circuit from a circuit with a capacitive charging current in a three-phase electrical power distribution system comprising three phase conductors and a neutral, the method comprising: measuring current through one or more phase conductors; measuring current through the neutral and establishing a base angle for vector comparison for the phase conductors; and comparing the magnitude and phase angle of the current of one or more of the phase conductors between the magnitude and base angle of the current of the neutral to determine whether or not current is flowing through a faulted circuit.

Aspect 15 is the method of Aspect 14, wherein current is measured using a magnetometer. Aspect 16 is the method of Aspect 15, wherein the magnetometer converts a magnetic field to an output voltage through magnetoresistance. Aspect 17 is the method of Aspect 15 or 16, wherein the magnetometer comprises a ferromagnetic thin film permalloy. Aspect 18 is the method of any of Aspects 14-17, wherein the phase conductors are surrounded by a toroid-shaped magnetic core, the core comprises an opening, and the magnetometer is disposed in the opening.

Aspect 19 is the method of any of Aspects 14-18, wherein the magnetic core comprises steel, and optionally laminated steel.

Aspect 20 is a device for detecting a ground fault current, comprising a toroid-shaped magnetic core with a gap in the core and a sensor disposed in the gap.

Aspect 21 is the device of Aspect 20, wherein the magnetic core has a C-shaped structure and is operably configured for surrounding one or more phase conductors, preferably of a three-phase electrical power distribution system.

Aspect 22 is the device of Aspect 20 or 21, wherein the sensor comprises a magnetoresistant material.

Aspect 23 is the device of Aspect 22, wherein the magnetoresistant material is a ferromagnetic thin film permalloy.

Aspect 24 is the device of any of Aspects 20-23, wherein the magnetic core comprises laminated steel.

Aspect 25 is a three-phase electrical power distribution system comprising: three phase conductors and a neutral connected together at a Wye transformer; a device for detecting ground fault current, the device comprising a toroid-shaped magnetic ring configured with an opening, and a sensor is disposed in the opening; wherein the magnetic ring surrounds one or more of the three phase conductors.

Aspect 26 is the three-phase electrical power distribution system of Aspect 25 comprising multiple devices for detecting ground fault current, wherein one device surrounds each phase conductor.

Aspect 27 is the three-phase electrical power distribution system of Aspect 25 or 26, wherein the sensor comprises a magnetoresistant material.

Aspect 28 is the three-phase electrical power distribution system of Aspect 27, wherein the magnetoresistant material is a ferromagnetic thin film permalloy.

Aspect 29 is the three-phase electrical power distribution system of any of Aspects 25-28, wherein the magnetic ring comprises laminated steel.

Aspect 30 is the three-phase electrical power distribution system of any of Aspects 25-29, wherein the neutral is connected to ground and a resistor is placed between neutral and ground.

Aspect 31 is the three-phase electrical power distribution system of any of Aspects 25-30, wherein the device for detecting ground fault current is operably configured to measure a magnetic field intensity in the opening of the magnetic ring through the sensor, such that the magnetic field intensity is proportional to ground current that enters the magnetic ring and returns outside the ring, and the sensor outputs a voltage that is proportional to the magnetic field intensity in the opening.

Aspect 32 is the three-phase electrical power distribution system of any of Aspects 25-31, further comprising a voltage regulator in operable connection with the sensor.

Aspect 33 is the three-phase electrical power distribution system of any of Aspects 25-32, further comprising a power supply in operable connection with the voltage regulator.

Aspect 34 is the three-phase electrical power distribution system of any of Aspects 25-33, further comprising an amplifier in operable connection with the sensor, wherein the amplifier receives a voltage output from the sensor.

Aspect 35 is the three-phase electrical power distribution system of any of Aspects 25-34, further comprising a circuit breaker on each of the three phase conductors.

Aspect 36 is the three-phase electrical power distribution system of any of Aspects 25-35, further comprising a tripping device in operable connection with the amplifier and the circuit breakers.

Aspect 37 is the three phase electrical power distribution system of any of Aspects 25-36, further comprising one or more processors in operable connection with the sensor(s) individually or collectively, an amplifier, and/or a tripping device.

Aspect 38 is the three phase electrical power distribution system of Aspect 37, wherein the processors are operably configured to compare magnitude of current in one or more of the three phase conductors with magnitude of current in the neutral.

Aspect 39 is the three phase electrical power distribution system of Aspect 37 or 38, wherein the processors are operably configured to compare phase angle of current in one or more of the three phase conductors with magnitude of current in the neutral.

Aspect 40 is the three phase electrical power distribution system of any of Aspects 37-39, wherein the processors are operably configured to identify a circuit with a fault by way of comparison between magnitude and/or phase angle of current in one or more of the three phase conductors and the neutral.

Aspect 41 is the three phase electrical power distribution system of any of Aspects 37-40, wherein the processors are operably configured to identify a circuit with a fault and send a signal to a tripping device to activate a trip of a circuit breaker of the faulted circuit.

Aspect 42 is a method of detecting ground current comprising: measuring magnetic flux generated by power conductors of a three phase electrical power distribution system using a detector; wherein the magnetic flux is indicative of an amount of current diverted to ground and wherein optionally the sensor converts the magnetic flux to a voltage output; and/or wherein optionally milliampere currents are measured.

Aspect 43 is the method of Aspect 42, wherein the detector surrounds the power conductors and comprises a magnetic core in operable communication with a sensor, wherein the sensor is disposed in a gap within the magnetic core.

Aspect 44 is the method of any of Aspects 1, 2, 4-6, 9, 10, 12, 13, 15, 16, 18-19, 42 or 43, wherein the sensor is an alloyed glass crystal.

Aspect 45 is the device of any of Aspects 20-22 or 24, wherein the sensor is an alloyed glass crystal.

Aspect 46 is the system of any of Aspects 25-27 or 29-41, wherein the sensor is an alloyed glass crystal.

Aspect 47 is a method of operating a power distribution system and of tripping a breaker of a faulted circuit of the system, the method comprising: (1) monitoring neutral current with a first sensor; (2) monitoring ground current of one or more circuits with a second sensor; (3) engaging a time delay breaker trip when the ground current is above a trip threshold; (4) comparing the ground current of the circuit with the neutral current and engaging a breaker trip of a faulted circuit when the circuit ground current does not lead the neutral current by a specified amount.

Aspect 48 is a method of detecting a fault in an electrical power distribution system, the method comprising: summing currents in power conductors of a circuit to determine a fault condition; determining one or both of magnitude and phase angle of the current in each power conductor and of a current in neutral; and comparing the magnitude and/or phase angle of one or more of the power conductors to that of the current in neutral; and determining by way of the comparing which power conductor has a fault and/or which power conductor has capacitive charging current; wherein optionally the summing is performed using a detector comprising a sensor operably configured to measure magnetic field intensity and operably configured to output a voltage that is proportional to the magnetic field intensity; and/or optionally wherein the electrical power distribution system is a three-phase electrical power distribution system.

The present invention is also distinguished from conventional ground fault detection systems by the fact that the current flow through the neutral and neutral grounding resistor, if used, does not contain the capacitive charging current of the cables of the non-faulted circuits. Embodiments of the invention include establishment of the base angle for vector comparison with each output circuit to determine which circuit has a fault, and which has only capacitive charging current, by using the current flow through the neutral and neutral resistor. In contrast to the present invention, conventional systems do not rely on the essentially unknown physical characteristic that the capacitor charging current does not flow through the neutral during a fault.

### BRIEF DESCRIPTION OF THE DRAWINGS

The accompanying drawings illustrate certain aspects of embodiments of the present invention, and should not be used to limit or define the invention. Together with the written description the drawings explain certain principles of the invention.

FIG. 1 is a schematic circuit diagram showing a Wye-connected three phase electrical power distribution system with a neutral point connected to ground.

FIG. 2 is a schematic circuit diagram of a Wye-connected three phase electrical power distribution system with a neutral point connected to ground, wherein a resistor intervenes between the source neutral and ground.

FIG. 3 is a schematic circuit diagram showing a Wye-connected three phase electrical power distribution system with a neutral connected to ground, wherein a resistor intervenes between the source neutral and ground and a circuit is faulted.

FIG. 4A is a schematic diagram showing a conventional window current transformer for sensing ground faults.

FIG. 4B is a schematic diagram showing an embodiment of a ground fault sensing device according to the invention.

FIG. 5 is an illustrative block diagram showing an embodiment of a ground fault detection system according to the invention.

FIG. 6 is a flowchart showing a method embodiment of the invention for determining a faulted circuit in an electrical system.

FIG. 7A is a flowchart showing a method of operating a power distribution system and of tripping a breaker of a faulted circuit of the system.

FIG. 7B is a flowchart showing a more detailed method of FIG. 7A.

FIG. 7C is a graph showing a ground fault determination example of the methods illustrated in FIGS. 7A-B.

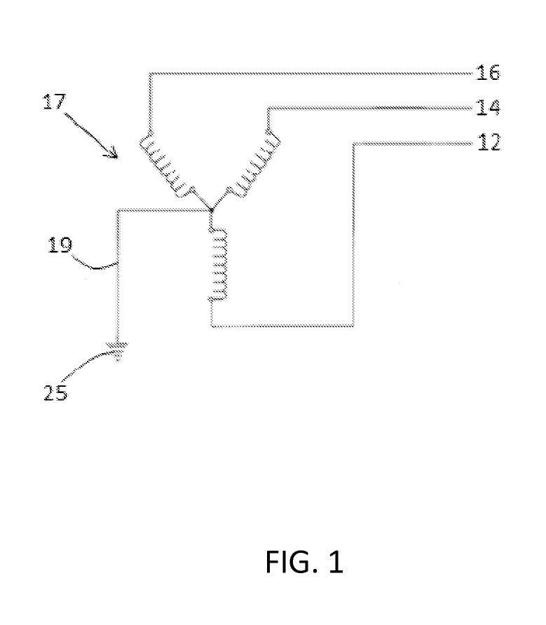

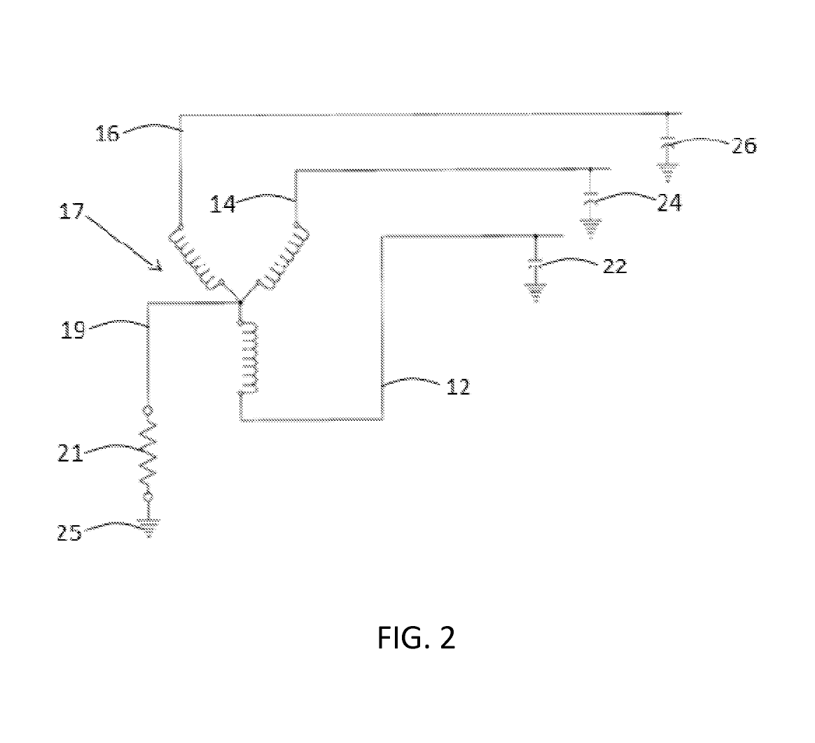

### DETAILED DESCRIPTION OF VARIOUS EMBODIMENTS OF THE INVENTION

Reference will now be made in detail to various exemplary embodiments of the invention. It is to be understood that the following discussion of exemplary embodiments is not intended as a limitation on the invention. Rather, the following discussion is provided to give the reader a more detailed understanding of certain aspects and features of the invention.

Typical power systems are configured with multiple circuits feeding from the main bus. These circuits can have considerable length and may be of shielded cable resulting in enough inherent capacitance from the power conductors to ground to produce tripping levels of capacitive current flow on an unfaulted circuit during a fault on one of the other circuits. This loss of selective tripping results in the false tripping of good circuits with the associated dangers and inconvenience of critical circuit tripping.

To address this issue, an embodiment of the present invention uses a ground fault sensing device with a window-shaped magnetic core. In the context of this specification, the ground fault sensing device or components thereof may also be referred to generally as a sensor, or as a detector. The window-shaped magnetic core is configured such that the power conductors of the electrical distribution system pass through the window where the sum of the currents can be determined. The magnetic flux generated by the current in each conductor is concentrated in the magnetic material of the core. The sum of the currents in an electrical circuit is equal to zero. Therefore, the flux in the core is equal to zero if no current is diverted from the power conductors to return to the source outside of the core. Any current diverted to ground that does not return to the source through the window will generate flux in the core. This flux can be used to determine how much current is being diverted. The level of sensitivity of the detector determines how small the diverted current can be and be detected. In one embodiment, a sensitive magnetometer is placed in a thin gap in the core to measure this flux and convert it to a useful voltage output. The sensor preferably uses a magnetoresistive material to detect flux in the core which results in an extremely sensitive method of ground current detection resulting in measurements in the low milliamp range. Not wishing to be bound by a particular theory, the difference in magnitude and/or the phase angle between the sensed circuit current and the current in the neutral can be used to determine if the current is inherent capacitive current or a ground fault.

In one embodiment, the present invention provides a method of distinguishing a faulted circuit from a circuit with a capacitive charging current in a three-phase electrical power distribution system comprising three phase conductors and a neutral, the method comprising measuring current through the phase conductors, measuring current through the neutral, and comparing the quantity and/or phase angle between the current through the phase conductors and current through the neutral to distinguish a faulted circuit from a circuit with a capacitive charging current. The current measured by a sensor on a circuit is compared to the current measured by the neutral sensor and if the circuit current leads the neutral current in time by a preset amount it is deemed to be capacitive and a block is applied to the circuit breaker trip signal.

In another embodiment, the present invention provides a method of distinguishing a faulted circuit from a circuit with a capacitive charging current in a three-phase electrical power distribution system comprising three phase conductors and a neutral, the method comprising measuring current through the phase conductors, measuring current through the neutral to establish a base angle for vector comparison for the phase conductors, and comparing the magnitude and/or phase angle of the current of the phase conductors between the magnitude and base angle of the current of the neutral to determine whether or not current is flowing through a faulted circuit.

In another embodiment, the present invention provides a method of detecting ground current comprising a three-phase electrical power distribution system comprising three phase conductors, the method comprising providing a magnetic core, wherein each of the three phase conductors is disposed in the core, providing a sensor in communication with the magnetic core, and measuring magnetic flux in the magnetic core through the sensor, wherein magnetic flux is indicative of an amount of current diverted to ground and the sensor converts the magnetic flux to a voltage output.

In another embodiment, the present invention provides a method of detecting a ground fault in a three-phase electrical power distribution system comprising three phase conductors and a neutral in a manner such that a circuit with a ground fault is distinguished from a circuit with a capacitive charging current, comprising providing a magnetic core and a sensor, wherein the three phase conductors are surrounded by the magnetic core, the magnetic core comprises an opening, and the sensor is disposed in the opening, and the sensor comprises a magnetoresistive material with a capability to change its electrical resistance in response to a magnetic field in the range of the sensor, measuring the magnetic field intensity in the opening through the sensor, wherein the magnetic field intensity is proportional to ground current that enters the core and returns outside the core, and the sensor outputs a voltage that is proportional to the magnetic field intensity in the opening, and comparing one or both the magnitude and phase angle between the current through the phase conductors and the current through the neutral to determine which circuit(s) have a fault and which circuit(s) have capacitive charging current.

Another embodiment of the invention provides a device for detecting a ground fault current, comprising a toroid-shaped magnetic ring configured with an opening, and a sensor disposed in the opening. In embodiments, the sensor may comprise a magnetoresistant material. The shape of the ring is not critical and can be other shapes as well, including square, rectangular, or triangular for example. The magnetoresistant material may be a ferromagnetic thin film permalloy and the magnetic ring may comprise laminated steel.

Another embodiment of the invention comprises a three-phase electrical power distribution system comprising three phase conductors and a neutral connected together at a Wye transformer, a device for detecting a ground fault current, wherein the device comprises a toroid-shaped magnetic ring configured with an opening, and a sensor is disposed in the opening, wherein the magnetic ring of the device surrounds the three phase conductors.

Embodiments of the three-phase electrical power distribution may further comprise a voltage regulator in operable connection with the sensor, a power supply in operable connection with the voltage regulator, an amplifier in operable connection with the sensor, wherein the amplifier receives a voltage output from the sensor, or a tripping device in operable connection with the amplifier. Further, embodiments of the three phase electrical power distribution system may further comprise a processor in operable connection with the sensor, the amplifier, or the tripping device. Where multiple sensors are used, multiple processors or a single processor can be used to process the data. In embodiments, the processor may compare the magnitude of the current through the three phase conductors with the magnitude of the current of the neutral, or it may compare the phase angle of the current through the three phase conductors with the phase angle of the current of the neutral, or it may perform both comparisons.

In embodiments, the processor may identify a circuit with a fault through the comparison of the magnitude and phase angle of the current between the three phase conductors and the neutral, and may send a signal to the tripping device to activate it to trip the circuit breaker of the circuit identified with a fault. Sensors can also be present on the main bus, however, in preferred embodiments in determining whether there is a true fault, no comparison is made between measurements taken on the main bus (such as capacitive charging currents flowing therethrough) and measurements taken on the feeder circuits. For example, according to embodiments of the invention, accurate fault determinations can be made without reference to fault signals generated on the main bus. Further, in embodiments, voltage detection can be employed, for example, by using a voltage unbalance detection device for detecting a voltage unbalance among phases of the power supply, however, in preferred embodiments, voltage detection and/or comparisons, impedance detection and/or comparisons, and/or admittance detection and/or comparisons may be omitted and/or not used for determining whether a true fault exists in the system.

In any embodiment of the invention, a toroid-shaped magnetic ring or core may surround the three phase conductors and optionally the neutral, the toroid-shaped magnetic ring may comprise an opening, or air gap, and a sensor may optionally be disposed in the opening or air gap. In any embodiment, the sensor may measure the magnetic flux that results from current being diverted to ground as a result of a fault. In any embodiment, the sensor may comprise a magnetoresistive material disposed in a sensor, and the magnetostrictive material may be a ferromagnetic thin film permalloy. In any embodiment, the sensor may convert the magnetic flux to a voltage output through the magnetoresistive material. In any embodiment, the toroid-shaped magnetic ring surrounding the phase conductor and optionally the neutral may comprise a laminated steel core. In any embodiment, current may be measured through the phase conductors and optionally the neutral through a magnetometer. In any embodiment, the magnetometer can be used to convert a magnetic field to an output voltage through magnetoresistance.

In an exemplary embodiment, the present invention advantageously uses a highly sensitive magnetometer device to detect ground faults. In a preferred embodiment, the highly sensitive magnetometer device comprises a sensor that operates on magnetoresistance. In a specific embodiment, the sensor may comprise a thin film permalloy material (such as nickel-iron). The basic principle of magnetoresistance as the variation of the resistivity of a material or a structure as a function of an external magnetic field, is generally described by the following equation (see Reig et al., Magnetic Field Sensors Based on Giant Magnetoresistance (GMR) Technology: Applications in Electrical Current Sensing, Sensors (Basel). 2009; 9(10): 7919-7942 “Reig et al., 2009”):

R=f(B)

Ferrous material including permalloy uses the Anisotropic Magneto Resistive (AMR) effect. (See Honeywell, Magnetoresistive Sensors, 2013, http://sensing.honeywell.com/index.php?ci_id=50272). The anisotropic term results from dependence on the angle between the electrical current and the magnetization direction. (See Reig et al., 2009″). Typically, the AMR effect can be described as a change in the scattering due to the atomic orbitals caused by a magnetic field. The resistance is thus at maximum when both directions are parallel and resistance is at minimum when both directions are perpendicular. AMR can be expressed by the following equation (see Reig et al., 2009):

R=R₀+Δ cos² θ

When current is passed through a ferromagnetic material, such as a permalloy, the internal magnetization vector (M) of the ferromagnetic material is parallel to the current flow. When applying an external magnetic field opposite to the direction of the current flow, the internal magnetization vector changes its position to M1 by an angle that depends on the strength of the magnetic field. The resistance of the material is directly dependent on the angle formed by the internal magnetization vector (M) of the ferromagnetic material and the direction of the current (I) flow. If the current flow and the internal magnetization vector are parallel, the resistance is largest. If the angle between the current flow and the internal magnetization vector is 90°, the resistance in the ferromagnetic material is smallest. (See Madhav A., Racetrack Memory, 2013, http://www.scribd.com/doc/68867775/Racetrack-Memory).

Magnetic response for an individual magnetoresistor can be expressed as the ratio of the change in resistance ΔR over the nominal resistance Ri of the film. (see Honeywell, 2013). Magnetoresistive responses are polarity insensitive, such that the response to a positive field is the same as the response to a negative field. In addition, there is a region which is reasonably linear. However, it is possible for the magnetoresistive effect to go into saturation when the absolute value of the external field exceeds a particular value. (see Honeywell, 2013).

With respect to permalloy, when an external magnetic field (B) is applied, the film's resistance changes proportional to the square of the sine of the angle θ (theta in the XZ plane) between the magnetization vector (M) and current flow vector (I). (see Honeywell, 2013). The magnetization vector is the net summation of the film's internal fields and the applied external field.

In contrast, Hall effect sensors only respond to a specific polarity (North or South). The Hall effect coefficient for a particular material can be defined as

$${R}_{H} = \frac{{E}_{y}}{{j}_{x} B}$$

where j is the current density of the carrier electrons, and E_{y} is the induced electric field. (see http://www.tf.uni-kiel.de/matwis/amat/mw2_ge/kap_{—}2/backbone/r2_{—}1_{—}3.html).

In addition, the amount of generated voltage due to the Hall effect, VH, can be calculated using the relationship

VH=[B*KH*I]/z

where B=Flux density of magnetic field [Wb/m2 or tesla (T)]

KH=Hall effect constant (m3/number of electrons-C)

I=Current flowing through the conductor (A) and

Z=Thickness of conductor (m)

(see Patterson, Hall Effect Sensors and Magnetoresistance, 2013, http://academic.udayton.edu/markpatterson/ECT459/Hall Effect.pdf).

The Hall effect constant, KH, is a factor of the number of electrons per unit volume and the electron charge.

Sensors based on magnetoresistance are considerably more sensitive (for example up to 50-100 times more sensitive than Hall-effect sensors) and thus do not require a built-in amplifier which is typical of Hall effect sensors. Further, while Hall-effect sensors respond to fields perpendicular to the sensor, AMR films optimally respond to parallel fields. These and other advantages of magnetoresistive sensors over Hall effect sensors can be appreciated by a skilled artisan. Magnetoresistive sensors are preferred embodiments of magnetometers for the present invention as they provide distinct advantages over Hall effect sensors in both the sensitivity and directionality of magnetic field detection.

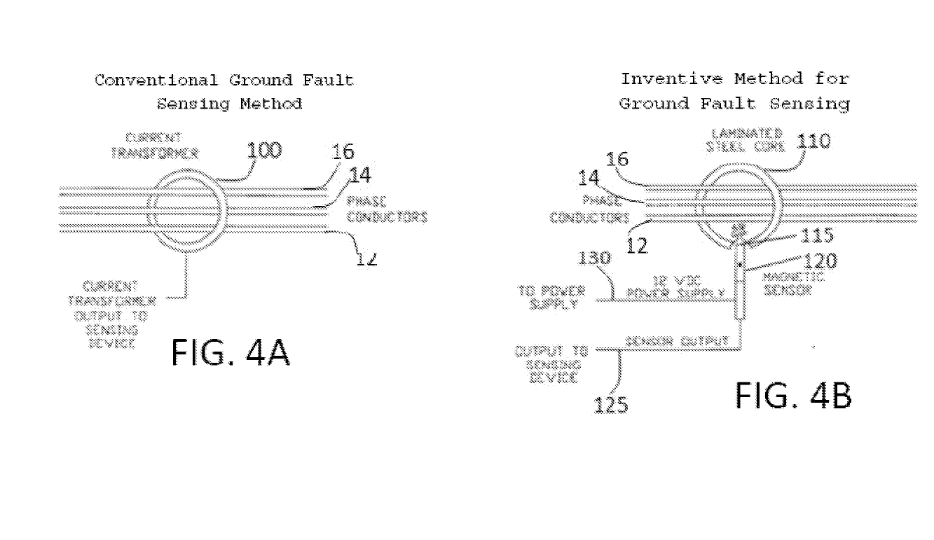

In embodiments, the magnetometer device of the present invention may be a toroid-shaped core, such as a ring of magnetic metal 110 that sums the phase currents of a circuit, as shown in FIG. 4B. The magnetometer device is preferably configured to measure alternating current. A thin opening, or air-gap 115 may be cut through the steel 110 and an extremely sensitive magnetic sensor 120 employing a magneto-resistive thin film can be placed within the gap. The thin film may comprise any ferromagnetic material. In one embodiment, the thin film is permalloy. In embodiments, the sensor can be any metal or any metallic material or any material having one or more metallic properties, such as being magnetic and/or electrically conductive or semi-conductive, and being capable of emitting a signal in response to being subjected to magnetic flux. In embodiments, the sensor can be an alloyed glass crystal, such as a glass-like material comprising for example chromium which may be in the form of a chromate. Sensors of embodiments of the invention may comprise one or more of copper, gold, aluminum, zinc, nickel, brass, bronze, iron and/or platinum, or any alloy containing one or more of the materials specified for the sensors as detailed in this specification. For example, in particular embodiments, the crystals can be optical crystals, such as those provided by CASIX and/or Al RAK. The crystals can be used in sensors to determine the amount of magnetic flux by measuring the deflection of a laser beam within the crystal, which deflection is caused by the magnetic flux present.

The sensor output voltage 125 is proportional to the magnetic field in the core gap 115 and is proportional to ground current that goes through the core window and returns outside the core window on the ground system. The sensor may also be connected 130 to a power supply. Embodiments of the device of the invention may measure currents in the low milliampere range. A magnetic ring or core with magnetic sensor disposed in the opening or air gap may surround each of the three phase conductors in a 1:1 ratio, or one magnetic ring or core with magnetic sensor may surround all three phase conductors in a 1:3 ratio as shown in FIG. 4B. The magnetic metal of the ring or core may be any suitable magnetic metal, such as laminated steel. In other embodiments, the magnetic metal of the ring or core may be iron, nickel, cobalt, gadolinium, neodymium, or samarium, or may be any composite or alloy comprising one or more of these metals.

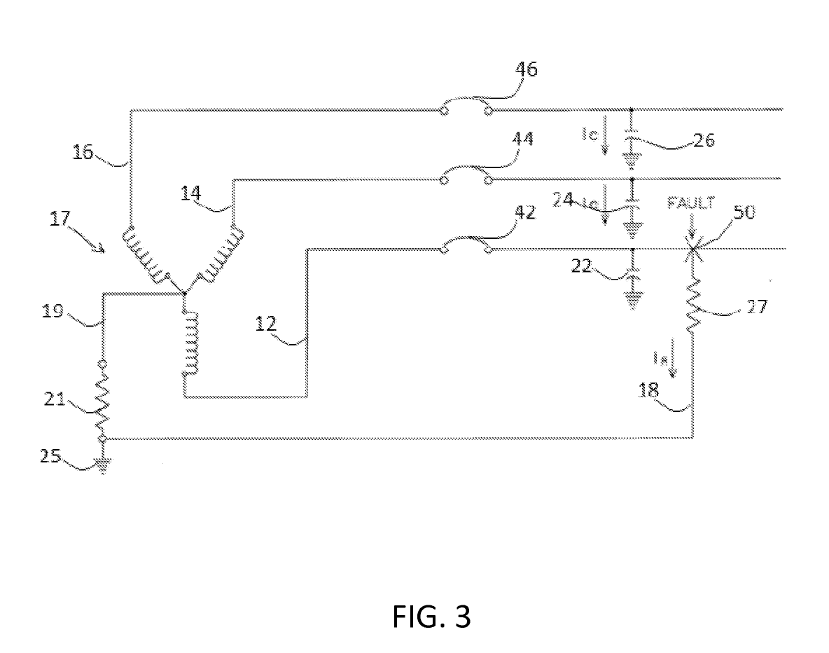

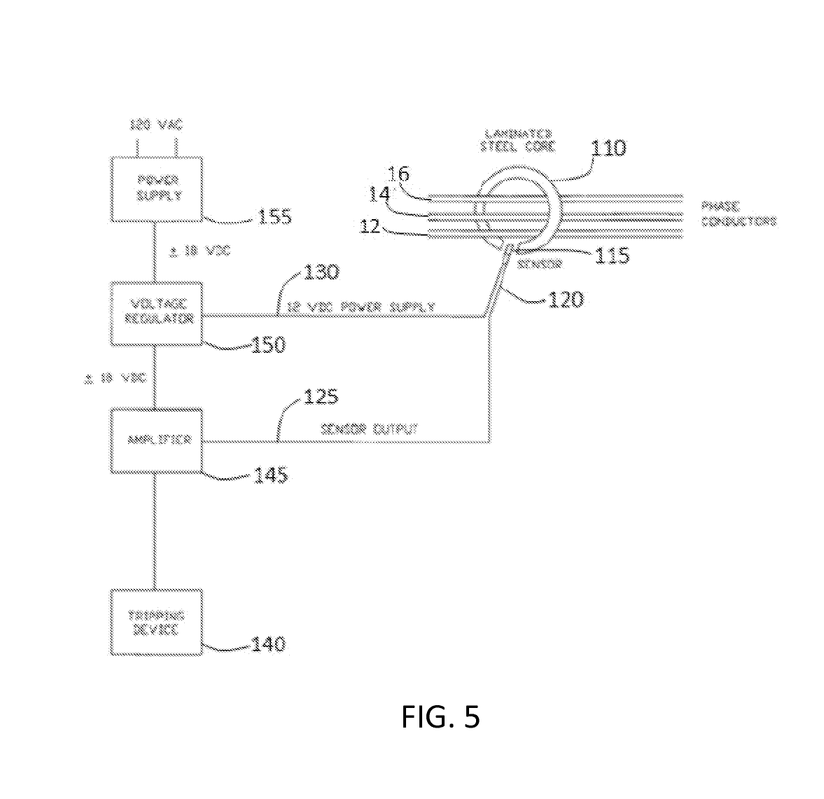

Considering FIG. 3 with FIG. 5, the three-phase electrical power distribution system may comprise three phase conductors 12, 14, 16 and a neutral 19 connected together at a Wye transformer 17, a device for detecting a ground fault current in one or more or each three phase conductor 12, 14, 16, where the device comprises a toroid-shaped magnetic ring or core 110 configured with an opening or air gap 115, and a sensor 120 is disposed in the opening, and the magnetic ring 110 of the device may surround one or more of the three phase conductors 12, 14, 16, separately or together. In other embodiments (not shown), the magnetic ring 110 (with opening 115 and sensor 120) may also surround the neutral 19 in addition to the three phase conductors 12, 14, 16, or a separate magnetic ring 110 (with opening 115 and sensor 120) may surround the neutral 19. The sensor may comprise a magnetoresistant material, which may be a ferromagnetic thin film permalloy. The magnetic ring may comprise laminated steel. The neutral 19 may be connected to ground 25, and a resistor 21 may be placed between neutral 19 and ground 25. The device may measure the magnetic field intensity in the opening 115 through the sensor 120, such that the magnetic field intensity is proportional to ground current that enters the core and returns outside the core, and the sensor outputs a voltage that is proportional to the magnetic field intensity in the opening. The magnetic sensor 120 may be connected 130 to a voltage regulator 150, which is connected to a power supply 155, such as a 12 volt DC power supply. The magnetic sensor may also be connected to an external amplifier 145 for boosting the signal 125 of the sensor 120. The amplifier 145 may be further connected to a tripping device 140 for breaking a circuit in the event of fault detection. The tripping device may be operably connected to one or more of circuit breakers 42, 44, 46 of the three phase conductors 12, 14, 16 so that a breaker of a faulted circuit may be tripped. The circuit breakers may be any current-limiting device, including but not limited to air magnetic or vacuum circuit breakers or motor circuit protectors, air or vacuum contactors, solid-state power switching devices, or electronically-triggered fuses.

The system may further comprise a processor (not shown) in operable communication with the sensor or external amplifier. The processor may receive a voltage output from one or more or each of the magnetic sensors. The processor may be programmed to perform a comparison of one or both the quantity and phase angle between the sensed circuit current and current in the neutral to distinguish between inherent capacitive current and a ground fault. The processor may also be programmed to send a trip signal to a circuit breaker on a circuit or activate a tripping device upon identification of a ground fault.

The processor may be programmed to perform these operations by a group of computer-executable instructions that may be organized into routines, subroutines, procedures, objects, methods, functions, or any other organization of computer-executable instructions that is known or becomes known to a skilled artisan in light of this disclosure, where the computer-executable instructions are configured to direct a computer or other data processing device to perform one or more of the specified operations. The processor may be a stand-alone unit or may be part of be a general purpose computer, a special-purpose computer, or other programmable data processing apparatus and may include a form of computer-readable memory which may include random-access memory (RAM) or read-only memory (ROM). The computer-executable instructions can be embedded in computer hardware or stored in the computer-readable memory such that the computer or device may be directed to perform one or more of the processes and operations described herein. Alternatively, one or more operations such as a voltage comparison between the sensor outputs may be implemented strictly in hardware such as a voltage comparator.

The three phase power distribution system may be provided at any suitable voltage. For example, devices, systems, and methods of the invention can generally be used on low and medium voltage circuits. Voltages of basic systems are for example 120/208Y, 277/480Y, 346/600Y, 600/1040Y, 1387/2400Y, 2400/4160Y, 4160/7200Y, 7200/12470Y, and variations of these. In a Wye-connected embodiment, the system may be provided as a 230/400V system which provides 230V between the neutral and any one of the phases, and 400V across any two phases. The system may also be provided as a 260/450V system which provides 260V between the neutral and any one of the phases, and 450V across any two phases. The system may also be provided as a 277/480V system which provides 277V between the neutral and any one of the phases, and 480V across any two phases. The system may also be provided as a 120/208V system which provides 120V between the neutral and any one of the phases, and 208V across any two phases. The particular voltages of the three phase power distribution configuration will depend on the voltages supplied by the utility. Additionally, other embodiments of three phase power distribution systems may include other configurations such as delta-connected systems.

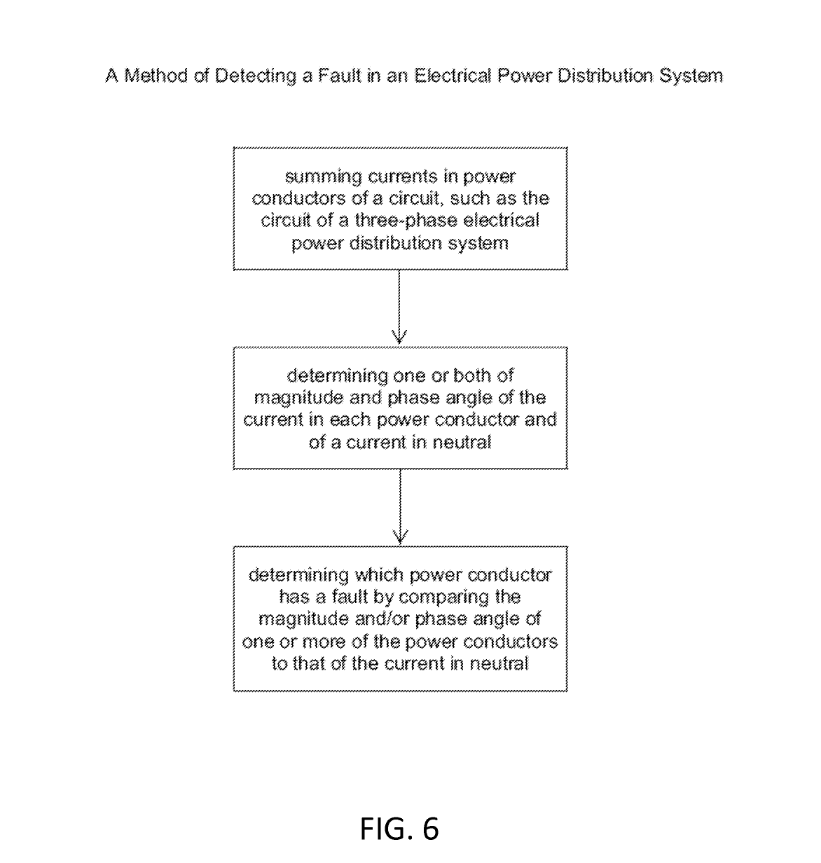

The systems and devices of embodiments of the invention can be used with any method of operation. Preferred methods can include a method of detecting a fault in an electrical power distribution system, which is illustrated in FIG. 6. Such methods can comprise: summing currents in power conductors of a circuit to determine a fault condition; determining one or both of magnitude and phase angle of the current in each power conductor and of a current in neutral; and comparing the magnitude and/or phase angle of one or more of the power conductors to that of the current in neutral; and determining by way of the comparing which power conductor has a fault and/or which power conductor has capacitive charging current; wherein optionally the summing is performed using a detector comprising a magnetic core and a sensor comprising a magnetoresistive material, which sensor is disposed within an opening of the magnetic core; and/or wherein optionally the magnetic core surrounds the power conductors; and/or wherein optionally the sensor is operably configured to measure magnetic field intensity, which is proportional to ground current that enters the core and returns outside the core, and the sensor is operably configured to output a voltage that is proportional to the magnetic field intensity; and/or optionally wherein the electrical power distribution system is a three-phase electrical power distribution system.

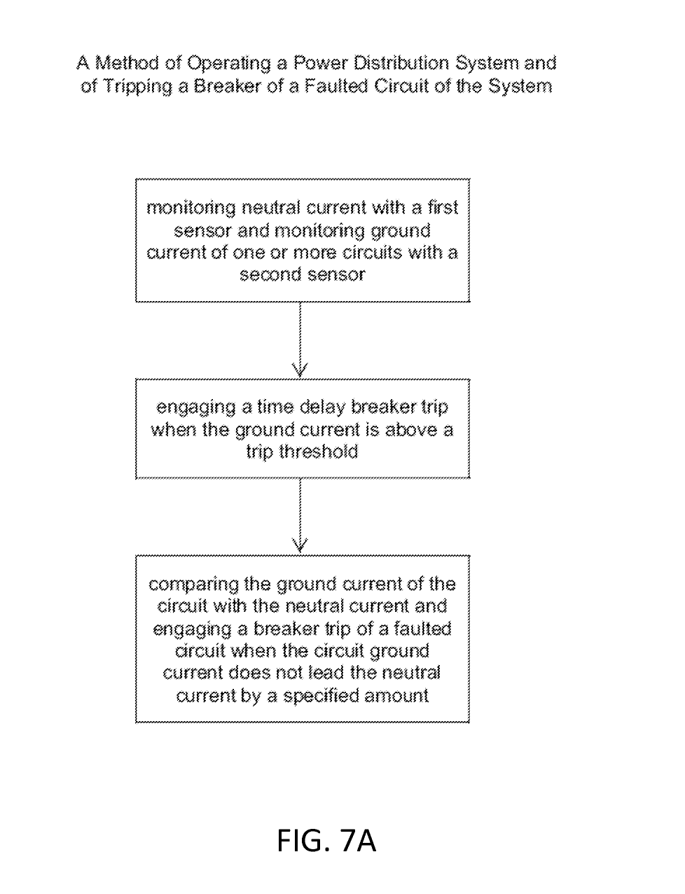

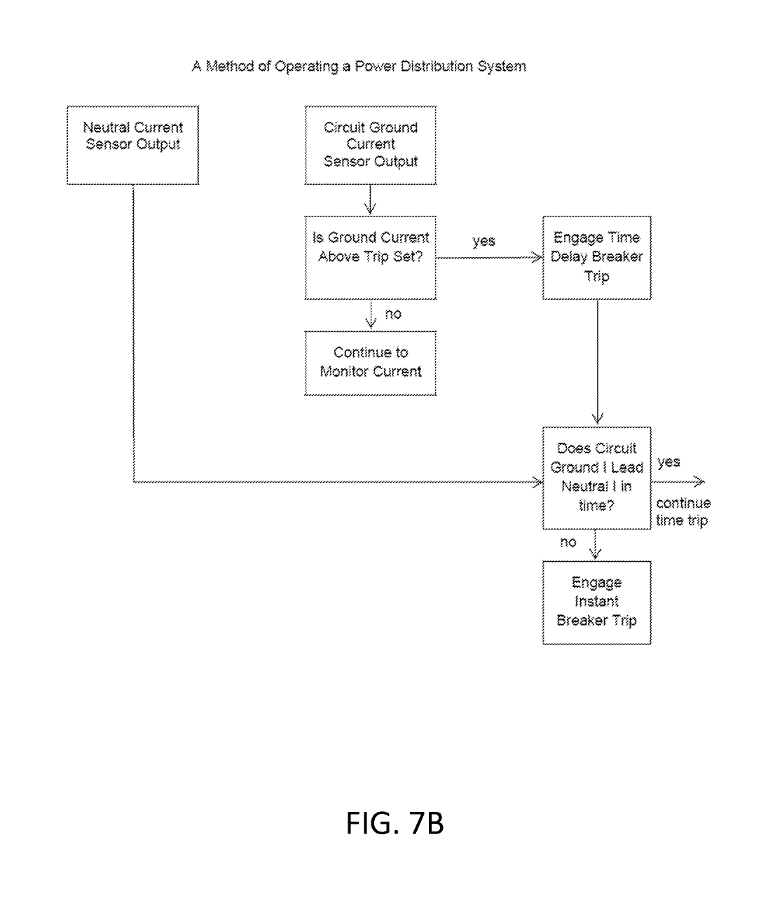

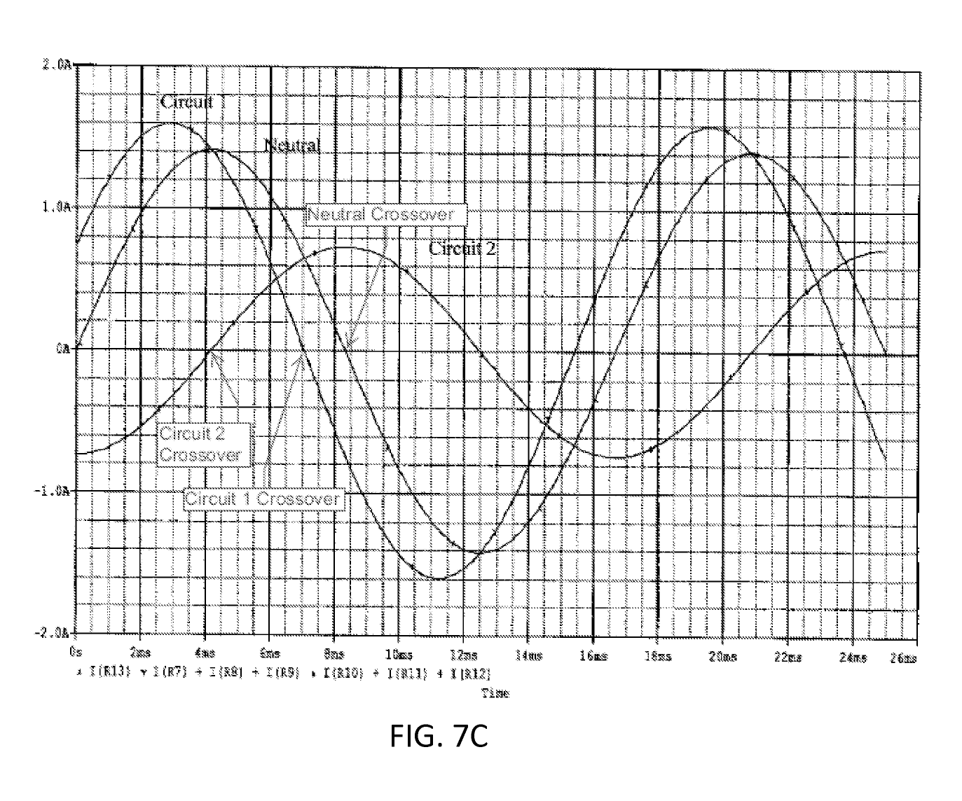

Additional methods of using the devices and systems of the invention, and/or other systems and devices for detecting faulted circuits, can include the method illustrated in FIG. 7A. As shown, a method of operating an electrical power distribution system and for tripping a breaker of a faulted circuit of the system is provided comprising: (1) monitoring neutral current with a first sensor; (2) monitoring ground current of one or more circuits with a second sensor; (3) engaging a time delay breaker trip when the ground current is above a trip threshold; (4) comparing the ground current of the circuit with the neutral current and engaging a breaker trip of a faulted circuit when the circuit ground current does not lead the neutral current by a specified amount.

Further provided in FIG. 7B is a flowchart showing a more detailed method of FIG. 7A. Here, current in the neutral is monitored as well as ground current in one or more power conductors. If the circuit ground current sensor output shows ground current above a set level, then the circuit breaker time delay trip is engaged. If the circuit ground current leads in time the neutral current by a specified amount, it is capacitive current, indicating a non-faulted circuit, and no corrective action is taken. If circuit ground current does not lead in time the neutral current by a specified amount, it is resistive current, which is an indication of a true faulted circuit. As corrective action, the breaker is provided a trip signal, which can be implemented at a desired time after the condition is present, such as instantly in response to the situation. One or more or all of the circuits under time delay trip can be automatically reset without tripping when the faulted circuit is cleared.

FIG. 7C is a chart illustrating a specific example of the methods illustrated in FIGS. 7A-B. As shown, an example is provided of two circuits of a multiple circuit system with a ground fault on one circuit. The system shown is an example of a 60 Hz system, but the principles involved are applicable to other types of systems as well. It is also noted at the outset that, typically, when a multiple circuit system is monitored, graphs are made to illustrate the relationship between one of the circuits and the neutral. Here, for convenience, all circuits are shown on the same chart. Parameters for this example are those of a typical long wall coal mining system: voltage is 4160 volts wye, neutral grounding resistor is 2400 ohms, cable phase resistance on each circuit is 0.346 ohms per phase, and cable phase to ground capacitance is 0.32 microfarad per phase. A ground is applied to Circuit 1. The cross-over point, i.e., the point at which the current in each circuit reaches 0 A for each circuit is indicated by the arrows in FIG. 7A, is used as a reference point for determining the timing of the current in each circuit relative to neutral. In this example, the timing differences are expressed in degrees, but can alternatively be expressed in seconds or any other equivalent measure of time.

In determining whether a ground fault exists in one or more circuits and in which circuit the ground fault is present, each circuit is monitored with a sensor and the timing of the current is compared with that of the current in the neutral. As explained in the previous examples, if a circuit leads the neutral circuit by a specified amount, then the current in that circuit is capacitive and the circuit is not faulted. If a circuit does not lead the neutral circuit by the specified amount, then the current in that circuit is resistive and the circuit is faulted. In this example, if the threshold is set at 45 degrees, any current in Circuit 1 or 2 leading current in the neutral by less than 45 degrees would be identified as a faulted circuit. Here, the ground current sensed in Circuit 1 leads the neutral current by only 41 degrees, so the current is identified as resistive and Circuit 1 is a faulted circuit, i.e., the current in Circuit 1 does not lead current in the neutral by at least 45 degrees. Additionally, the ground current sensed in Circuit 2 leads the neutral current by almost 90 degrees. Therefore, since the current in Circuit 2 leads current in the neutral by more than the threshold amount, 45 degrees, current in Circuit 2 is said to be capacitive and Circuit 2 is not a faulted circuit. Accordingly, Circuit 1 should be tripped and Circuit 2 should be blocked from tripping.

The methods, systems, and devices of the present invention are simple, robust, and unique and allow for the ever increasing need to develop extremely sensitive ground fault detection for three phase low and medium voltage systems. The present invention is useful for preventing the consequences of ground faults such as fire, flash burns, equipment damage, frame voltage rise, and electrical shock. The methods, systems, and devices are particularly advantageous at three phase electrical distribution systems in underground mining operations such as long wall operations, which require mechanical equipment with considerable horsepower, such as a shearer or crusher. The methods, systems, and devices can detect extremely low ground currents and provide both a sensitive and selective means for determining whether a circuit is faulted.

The present invention has been described with reference to particular embodiments having various features. It will be apparent to those skilled in the art that various modifications and variations can be made in the practice of the present invention without departing from the scope or spirit of the invention. One skilled in the art will recognize that the disclosed features may be used singularly, in any combination, or omitted based on the requirements and specifications of a given application or design. When an embodiment refers to “comprising” certain features, it is to be understood that the embodiments can alternatively “consist of” or “consist essentially of” any one or more of the features. Other embodiments of the invention will be apparent to those skilled in the art from consideration of the specification and practice of the invention.

Where a range of values is provided, each value between the upper and lower limits of that range is also specifically disclosed. The upper and lower limits of these smaller ranges may independently be included or excluded in the range as well. The singular forms “a,” “an,” and “the” include plural referents unless the context clearly dictates otherwise. It is intended that the specification and examples be considered as exemplary in nature and that variations that do not depart from the essence of the invention fall within the scope of the invention. Further, all of the references cited in this disclosure, such as non-patent literature, pending patent applications, published patent applications, and published patents, are each individually incorporated by reference herein in their entireties and as such are intended to provide an efficient way of supplementing the enabling disclosure of this invention as well as provide background detailing the level of ordinary skill in the art.

1. A method of detecting a fault in an electrical power distribution system, the method comprising:
summing currents in power conductors of a circuit to determine a fault condition;
determining one or both of magnitude and phase angle of the current in each power conductor and of a current in neutral; and
comparing the magnitude and/or phase angle of one or more of the power conductors to that of the current in neutral; and
determining by way of the comparing which power conductor has a fault and/or which power conductor has capacitive charging current.

2. The method of claim 1, wherein the summing is performed using a detector comprising a magnetic core and a sensor comprising a magnetoresistive material, which sensor is disposed within an opening of the magnetic core.

3. The method of claim 2, wherein the magnetic core surrounds the power conductors.

4. The method of claim 2, wherein the sensor is operably configured to measure magnetic field intensity, which is proportional to ground current that enters the core and returns outside the core, and the sensor is operably configured to output a voltage that is proportional to the magnetic field intensity.

5. The method of claim 1, wherein the electrical power distribution system is a three-phase electrical power distribution system.

6. The method of claim 2, wherein the sensor measures magnetic flux that results from current being diverted to ground as a result of a fault.

7. The method of claim 2, wherein the magnetoresistive material is a ferromagnetic thin film permalloy.

8. The method of claim 2, wherein the magnetic core is a toroid-shaped magnetic ring comprising a laminated steel core.

9. A method of detecting ground current comprising measuring magnetic flux generated by power conductors of a three phase electrical power distribution system using a detector, wherein the magnetic flux is indicative of an amount of current diverted to ground.

10. The method of claim 9, wherein milliampere currents are measured.

11. The method of claim 9, wherein the detector surrounds the power conductors and comprises a magnetic core in operable communication with a sensor, wherein the sensor is disposed in a gap within the magnetic core.

12. The method of claim 11, wherein the sensor converts the magnetic flux to a voltage output.

13. The method of claim 12, wherein the sensor converts the magnetic flux to a voltage output by way of a magnetoresistive material.

14. The method of claim 13, wherein the magnetoresistive material is a ferromagnetic thin film permalloy.

15. A method of distinguishing a faulted circuit from a circuit with a capacitive charging current in a three-phase electrical power distribution system comprising three phase conductors and a neutral, the method comprising:
measuring current through one or more phase conductors;
measuring current through the neutral; and
comparing (i) magnitude and phase angle of the current through one or more of the phase conductors and (ii) current through the neutral.

16. The method of claim 15, wherein current is measured through the phase conductors and the neutral using a magnetometer.

17. The method of claim 15, wherein the phase conductors are surrounded by a toroid-shaped magnetic core, the core comprises an opening, and the magnetometer is disposed in the opening.

18. The method of claim 17, wherein the magnetometer comprises a ferromagnetic thin film permalloy and the magnetic core comprises steel.

19. A device for detecting a ground fault current, comprising a toroid-shaped magnetic core with a gap in the core and a sensor disposed in the gap.

20. The device of claim 19, wherein the magnetic core has a C-shaped structure and is operably configured for surrounding one or more phase conductors, preferably of a three-phase electrical power distribution system.

21. The device of claim 19, wherein the sensor comprises a magnetoresistant material.

22. The device of claim 21, wherein the magnetoresistant material is a ferromagnetic thin film permalloy.

23. The device of claim 19, wherein the magnetic core comprises laminated steel.

24. The device of claim 19, wherein the sensor is an alloyed glass crystal.

25. The method of claim 1, wherein the sensor is an alloyed glass crystal.
